(19) United States
(12) Patent Application Publication
(10) Pub. No.: US 2012/0037989 A1
(43) Pub. Date: Feb. 16, 2012

(54) LDMOS HAVING SINGLE-STRIP SOURCE CONTACT AND METHOD FOR MANUFACTURING SAME

(75) Inventors: Hsueh-I Huang, Kaohsiung County (TW); Shuo-Lun Tu, Hsinchu (TW); Ming-Tung Lee, Taoyuan County (TW); Yin-Fu Huang, Hsinchu (TW); Shih-Chin Lien, Taipei County (TW); Shyi-Yuan WU, Hsinchu (TW)

(73) Assignee: MACRONIX INTERNATIONAL CO., LTD., Hsinchu (TW)

(21) Appl. No.: 12/857,288

(22) Filed: Aug. 16, 2010

(51) Int. Cl. H01L 29/78; H01L 21/336

(52) U.S. Cl. 257/343; 438/286; 257/E29.261; 257/E21.417

(57) ABSTRACT

LDMOS devices having a single-strip contact pad in the source region, and related methods of manufacturing are disclosed. The LDMOS may comprise a first well lightly doped with a first dopant and formed into a portion of a substrate, the first well having a drain region at its surface heavily doped with the first dopant, and a second well lightly doped with a second dopant formed in another portion of the substrate, the second well having a source region at its surface comprising first portions heavily doped with the first dopant directly adjacent second portions heavily doped with the second dopant. Also, the LDMOS device may comprise a field oxide at the upper surface of the substrate between the source and drain regions, and contacting the first well but separated from the second well, and a gate formed partially over the field oxide and partially over the source region. The LDMOS may also comprise contact pads in contact with the gate, and source and drain regions, wherein the contact pad in contact with the source regions comprises a single-strip of conductive material extending across the source region.

### BACKGROUND

1. Field of the Invention

This invention relates generally to laterally-diffuse metal-oxide semiconductor (LDMOS) devices, and more particularly to an LDMOS device having a single-strip electrical contact pad for the source region of the LDMOS device.

2. Background of the Invention

A double-diffused metal oxide semiconductor (DMOS) device is characterized by a source region and a backgate region, which are diffused at substantially the same time. DMOS devices may have either lateral or vertical configurations. A DMOS device having a lateral configuration (referred to herein as an LDMOS), has its source and drain at the surface of the semiconductor wafer. Thus, the current flow is lateral.

LDMOS devices are typically used in high voltage applications, and when designing such LDMOS devices, it is important that the device should have a very high breakdown voltage (V_{bd}), whilst also exhibiting, when operating, a low ON-resistance (R_{ON}). By designing LDMOS devices with low ON-resistance and high breakdown voltage, such devices will typically exhibit low power loss in high voltage applications. In addition, by exhibiting a low ON-resistance, a high drain current (I_{dsat}) can be achieved when the transistor is in saturation.

One problem when designing such LDMOS devices is that techniques and structures that tend to maximize V_{bd} tend to adversely affect the R_{ON} and vice versa. For example, in a conventional LDMOS device, a lighter concentration of doping in the wells can be provided as an N-minus (NM) region in order to reduce the electric field crowding at the gate edge. However, this lighter concentration well doping tends to increase the R_{ON}. In order to decrease the R_{ON}, it would be necessary to increase the doping concentration of the NM region, but in so doing the breakdown characteristic would be degraded, i.e., V_{bd} would be reduced. Another conventional approach is to provide insulating layers that seek to increase the breakdown voltage (V_{bd}) of the LDMOS device. However, it would be desirable to further improve the trade off between high breakdown voltage and reduced ON-resistance. The disclosed principles provide such an improvement in LDMOS devices.

### SUMMARY

In one embodiment of the disclosed principles, a laterally double-diffused metal oxide semiconductor (LDMOS) device is provided, which may comprise a first well lightly doped with a first conductive dopant and formed into a portion of a substrate, the first well having a drain region at its surface heavily doped with the first dopant. In addition, in such an embodiment, the LDMOS comprises a second well lightly doped with a second conductive dopant formed in another portion of the substrate, the second well having a source region at its surface comprising first portions heavily doped with the first dopant directly adjacent second portions heavily doped with the second dopant. Moreover, such an LDMOS may comprise a field oxide formed at the upper surface of the substrate between the source region and the drain region, the field oxide contacting the first well and separated from the second well by a distance. Also, the exemplary LDMOS may also include conductive contact pads in contact with the gate, the drain region, and the source region, wherein the contact pad in contact with the source regions comprises a single-strip of conductive material extending across the source region.

In another embodiment, an LDMOS device constructed as disclosed herein may comprise two first wells lightly doped with a first conductive dopant and formed into a portion of a substrate, the first wells each having a drain region at their surface heavily doped with the first dopant. In addition, such an exemplary LDMOS device may also comprise a second well lightly doped with a second conductive dopant formed in another portion of the substrate between the two first wells, the second well having a source region at its surface comprising first portions heavily doped with the first dopant directly adjacent second portions heavily doped with the second dopant. Additionally, the LDMOS device may further include first and second field oxides formed at the upper surface of the substrate between the source region and each of the drain regions, the first field oxide contacting one of the first wells and separated from the second well by a distance and the second field oxide contacting the other of the first wells and separated from the second well by a distance. First and second gates may also be included, where each gate is formed partially over one of the field oxides and partially over the source region, and each gate formed directly on a gate oxide. In such an embodiment, the device may also include a buried layer comprising the first dopant located directly under the second well. Conductive contact pads in contact with the gates, the drain regions, and the source region may then be provided, wherein the contact pad in contact with the source regions comprises a single-strip of conductive material extending across the source region.

In other aspects, methods of manufacturing an LDMOS device are disclosed. In one embodiment, an exemplary method may comprise lightly doping, with a first conductive dopant, a portion of a substrate to form a first well, and heavily doping the first well with the first dopant to form a drain region at its surface. Such an exemplary method may also comprise lightly doping, with a second conductive dopant, another portion of the substrate to form a second well, and heavily doping the second well with the first and second dopants to form a source region at its surface, wherein the source region comprise first portions heavily doped with the first dopant directly adjacent second portions heavily doped with the second dopant. Such a method may then include forming a field oxide at the upper surface of the substrate between the source region and the drain region, the field oxide contacting the first well and separated from the second well by a distance. Then, such a method may further comprise forming a gate partially over the field oxide and partially over the source region, and forming conductive contact pads in contact with the gate, the drain region, and the source region, wherein the contact pad in contact with the source regions comprises a single-strip of conductive material extending across the source region.

### BRIEF DESCRIPTION OF THE DRAWINGS

Features, aspects, and embodiments of the inventions are described in conjunction with the attached drawings, in which:

FIG. 1 illustrates a cross-sectional view of one embodiment of an LDMOS device found in the prior art;

FIG. 2 illustrates a plan view of the embodiment of an LDMOS device illustrated in FIG. 1;

FIG. 2A illustrates a table setting forth experimental measurements for an LDMOS device constructed according to the disclosed principles;

FIG. 3 illustrates a plan view of a conventional LDMOS device;

FIG. 4 illustrates a plan view of another embodiment of a source region that may be formed for an LDMOS device according to the disclosed principle; and

FIG. 5 illustrates a flow diagram of one embodiment of a method of manufacturing an LDMOS, such as the LDNMOS shown in FIGS. 1 and 2, in accordance with the disclosed principles.

### DETAILED DESCRIPTION

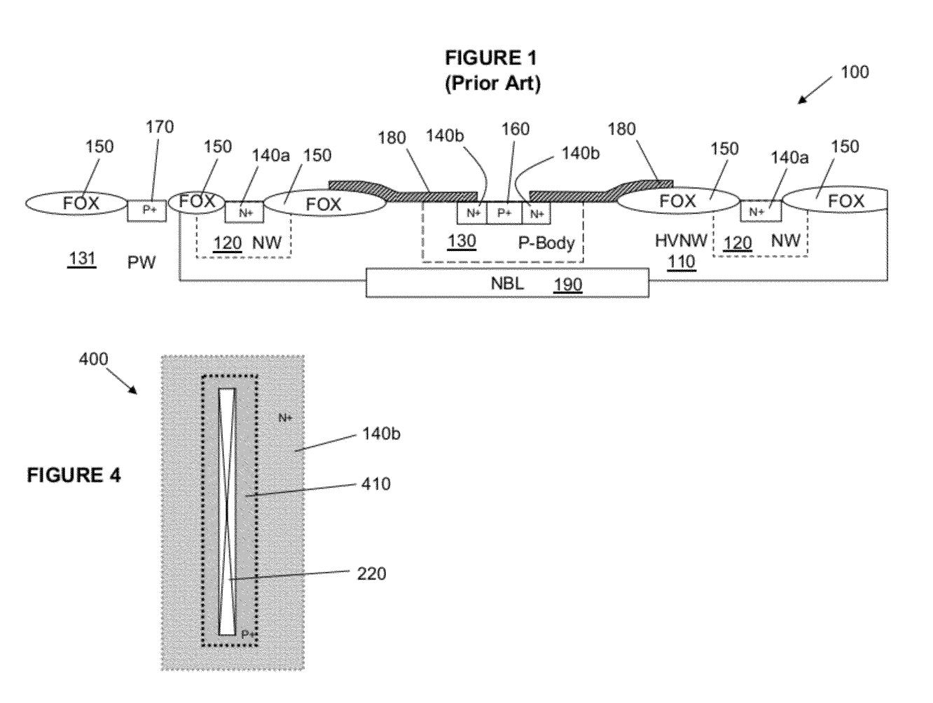

Looking initially at FIG. 1, FIG. 1 illustrates one embodiment of an LDMOS device 100 found in the prior art. As illustrated in FIG. 1, the LDMOS device 100 may include a high voltage n-type well (HVNW) region 110.

Also illustrated are N-type well (NW) regions 120 formed in the HVNW 110. In addition, a P-type well 130, which will serve as the P-type body of the illustrated LDMOS, is also formed in the HVNW 110. These regions may be formed using the exemplary process(es) described below. First N-type heavily doped regions 140a (at the LDMOS drain side area) are formed inside the lightly doped N-well regions 120 for the LDMOS 100. Additionally, second N-type heavily doped regions 140b are formed in P-body 130 to form portions of the source region for the LDMOS device 100. These regions 140a, 140b may be formed using the exemplary process(es) described below. Insulating regions, for example, field oxide (FOX) regions 150, are formed on the P-EPI to electrically insulate the LDMOS devices 100 from crosstalk, as well as PW 131. These FOX regions 150 may also be formed using the manufacturing process(es) described below.

Continuing with FIG. 1, a first P-type heavily doped region 160 is formed in the lightly doped P-body 130 of the LDMOS device 100, and between the N-type heavily doped regions 140b that are formed as part of the source region for the device 100. In addition, a second heavily doped P-type region 170 is formed in the P-EPI outside of HVNW 110 of the device 100. This second P-type heavily doped region 170 will form an ohmic contact to serve as the P-type well (PW 131) pick-up. As before, these heavily doped P-type regions 160, 170 may also be formed using the techniques described. Finally, gates 180 are formed over partially over the N-type regions 140b of the source area, and laterally extend onto insulting regions 150, which boost LDMOS Vbd and avoid oxide early breakdown while Vbd testing is conducted. The gates 180 may be formed from a variety of materials, and in one embodiment it is formed of polysilicon or doped polysilicon. An N-type buried layer (NBL) 190 is also present and underlies the source region 160 of the LDMOS device 100.

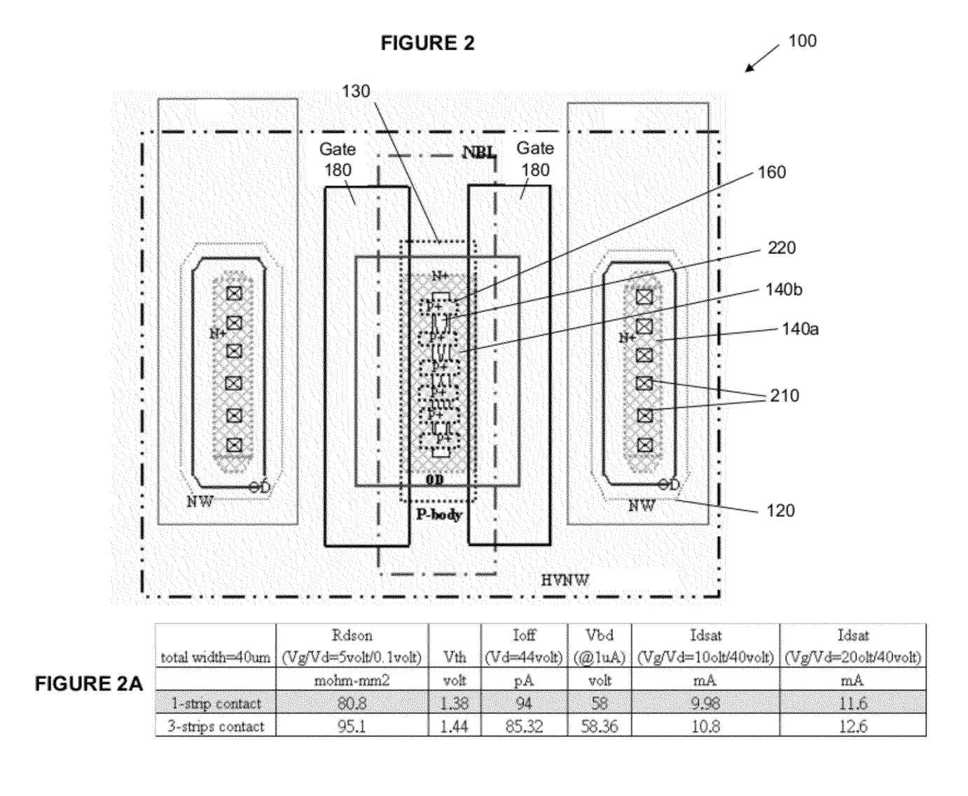

Turning now to FIG. 2, illustrated is a plan view of the LDMOS device 100 illustrated in FIG. 1. From this plan view, the various features of the LDMOS 100 may be seen in additional detail. These include the lightly doped HVNW 110, N-type wells (NW) 120 and P-Body 130, as well as the gates 180. Also illustrated are the heavily doped N-type drain regions 140a, and the heavily doped N-type regions 140b surrounding the heavily doped P-type source region 160 of the LDMOS device 100.

To electrically contact the N-type drain regions 140a from an electrical interconnect or other conductive line above the LDMOS device 100, conductive drain contact vias 210 are typically used. More specifically, since the drain regions 140a are elongated as illustrated in FIG. 2, a plurality of drain contact vias 210 are formed through interlevel dielectric layers and contact the drain regions 140a in multiple places.

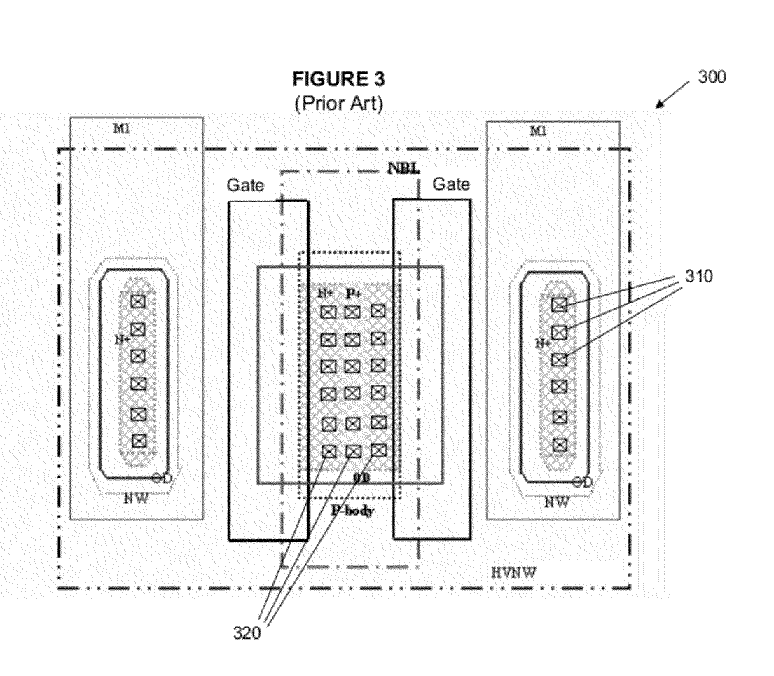

In contrast to conventional LDMOS devices, however, an LDMOS device constructed according to the principles disclosed herein, for example, LDNMOS 100 illustrated in FIGS. 1 and 2, includes only a single-strip contact 220 formed through the interlevel dielectric layers to contact the source region 160. Looking briefly at FIG. 3, illustrated is a conventional LDMOS device 300 constructed using conventional principles. As shown, conventional LDMOS devices not only include a plurality of contact vias 310 contacting the N-type drain regions of the device 300, but also includes a plurality of contact vias 320 contacting the N-type and P-type regions forming the source of the LDMOS device 300. In contrast, turning back to FIG. 2, the LDMOS device 100 according to the disclosed principles includes a single-strip contact 220 reaching down to the P-type regions 160 of the source for the device 100. By providing a single-strip contact for the source of the LDMOS device 100, the ON resistance of the LDMOS 100 is decreased (i.e., R_{d-sON}), as compared to similarly manufactured LDMOS devices having a plurality of contact vias contacting the device source region.

Experimental results achieved with LDNMOS devices constructed in accordance with the disclosed principles are set forth below in the Table illustrated in FIG. 2A. As illustrated, the ON-resistance [R_{dsoN}=Area×(V_{ds}/Idₗᵢₙₑₐᵣ)] may be decreased by about 17% when compared to a similarly manufactured conventional LDMOS having a plurality of source contact plugs (e.g., a 3-strip source contact). Additionally, the area of the LDMOS device 100 may be significantly decreased by forming a single-strip source contact as disclosed herein because the source region itself may be formed narrower than in conventional LDMOS devices. This is this case since the single-strip source contact occupies significantly less lateral area that the conventional plurality of source contact vias typically employed.

In addition to the above, the LDMOS device 100 illustrated in FIGS. 1 and 2 includes a plurality of P-type diffused regions 160 forming the P-type source region for the device 100. As such, the single strip contact 220 is formed so as to extend across all of the plurality of P-type strips forming the P-type region of the source of the LDMOS device 100. Looking now at FIG. 4, illustrated is another embodiment of a source region 400 that may be formed for the LDMOS device 100 according to the disclosed principles. In this disclosure, the heavily P-type doped areas (410) are islands, not a long strip. So, the N+ and P+ areas are in series.

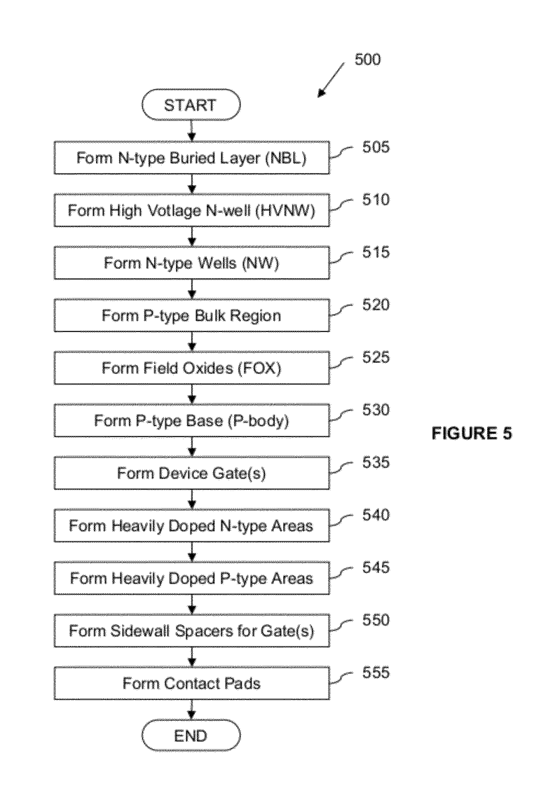

Turning now to FIG. 5, illustrated is a flow diagram 500 of one embodiment of a method of manufacturing an LDMOS, such as the LDNMOS shown in FIGS. 1 and 2, in accordance with the disclosed principles. Throughout the exemplary process(es) discussed herein, various exemplary and alternative techniques may be employed, and thus the disclosed principles should not be interpreted as being confined only to the examples discussed here. Moreover, some additional or intervening process steps, such as annealing or flushing process, may not be described herein, but may also be incorporated with the principles disclosed herein. The process begins at a Start step, where a silicon or other appropriate semiconductor substrate is provided, and any preliminary systems and processes are initialized and performed.

At a Step 505, an N-type buried layer (NBL) is formed. Specifically, in an exemplary embodiment, a photoresist mask is deposited for forming the underlying N-type buried layer. The deposited photoresist is then patterned and etched into the desired pattern and location for the N-type buried layer. An implantation is then performed through the patterned and etched photomask to from the N-type buried layer, and then the remaining photoresist material is removed from the substrate. In exemplary embodiments, the implantation may be followed by drive-in at a temperature of about 1200° C. and for a period of time of about 6 hours. Alternatively, other process parameters may be employed for implanting the N-type buried layer.

Next, at a Step 510, the high voltage N-well (HVNW) is formed. In an exemplary embodiment, an epitaxial layer, such as a P-type EPI layer, is located on the substrate and over the N-type buried layer (NBL). Then, a photoresist is deposited for forming the HVNW. The deposited photoresist is then patterned and etched into the desired pattern and location for the HVNW. An implantation is then performed through the patterned and etched photomask and into the EPI layer to form the HVNW in a desired portion of the P-type EPI layer. For example, in some embodiments, the implantation may be followed by drive-in at a temperature of about 1150° C. and for a period of time of about 1 hour. Alternatively, other process parameters may be employed for forming from the EPI layer. The remaining photoresist material is then removed from the substrate.

Following the formation of the HVNW, at a Step 515, the N-type wells (NW) may be formed in areas that will eventually become the drain regions for the LDNMOS device. In an exemplary embodiment, a photoresist is deposited. The deposited photoresist is then patterned and etched into the desired pattern and locations for the N-wells. An N-type dopant implantation is then performed through the patterned and etched photomask and into the HVNW to form the larger, lightly doped N-wells (e.g., NWs 120 in FIG. 1). In other embodiments, other process parameters may be employed for implanting the N-wells.

At a step 520, after formation of the N-wells, or perhaps even prior to the formation of the N-wells, a P-type implantation may be performed to form the P-type “bulk” regions (e.g., P-type region 131 in FIG. 1) surrounding the exterior of the LDNMOS device layout. In an exemplary embodiment, another photoresist mask is deposited over the HVNW. This photoresist mask is then patterned and etched into the desired pattern and locations for these P-type regions. A P-type dopant implantation is then performed through the patterned and etched photomask and into the HVNW to form these P-type areas of the LDMOS device. In exemplary embodiments, this P-type dopant implantation process may be followed by drive-in at a temperature of about 1150° C. and for a period of time of about 3 hours. In other embodiments, other process parameters may be employed for implanting the P-type regions. Moreover, as mentioned above, these P-type doped regions may be formed prior to the formation of the N-type doped, if desired. After implantation of these surrounding P-type doped regions, the remaining photoresist material is then removed from the device layout.

At a Step 525, the isolation regions, typically field oxide regions (e.g., FOXs 150 in FIG. 1), are formed. More specifically, a buffer oxide layer (e.g., a PADOX layer) may first be formed over the device layout. Additionally, this buffer oxide layer may also have a SiN layer or other sacrificial oxide layer (e.g., SACOX) deposited on the buffer oxide layer. Another photoresist is then deposited over these oxide layers, and patterned with the locations of the field oxide regions. The wafer is then processed to grow the field oxide regions through the openings in the photoresist mask, for example, using an LOCOS process. Of course, other oxide formation processes may also be employed. Once the field oxides are formed, the remaining photoresist material, as well any remaining SACOX, are removed from the device layout.

Next in the process, at a Step 530, the lightly doped P-base or P-body (e.g., P-body 130 in FIG. 1) may be formed. In an exemplary embodiment, another photoresist is deposited over the device layout, including the newly formed field oxide regions. This photoresist mask is then patterned and developed with the desired location of the lightly doped P-body region of the LDMOS device. A P-type dopant implantation is then performed through the patterned photomask and into the HVNW to form the P-body area of the LDMOS device. In other embodiments, other process parameters may be employed for implanting the P-body. Moreover, the P-body may be formed earlier in the manufacturing process, if desired. After implantation of the P-body, the remaining photoresist material is then removed from the device layout.

At a step 535, the gates for the LDMOS device (e.g., gates 180 in FIG. 1) may be formed. Specifically, a high voltage gate oxide layer may first be deposited over the device layout. Next, a low voltage gate oxide layer may be formed on top of the high voltage gate oxide layer. Of course, other appropriate oxides may also be employed. Once the high voltage and low voltage gate oxides layer are formed, the conductive gate material is then deposited over these gate oxide layers. In advantageous embodiments, polysilicon may be employed for the gate layer, but other semiconductor material(s) may also be employed. Additionally, a metal silicide layer, such as tungsten silicide, may also be deposited over the gate poly, which can undergo a salicide process for forming low resistance polygates. After gate formation is completed, the remaining photomask may then be removed from the device layout.

Next, at a Step 540, a second N-type implantation may be performed to form the heavily doped N-type regions (e.g., N+ 140a in FIG. 1) in the N-wells. Once again, a photoresist material is deposited over the device layout, and patterned with the locations for the N-type heavily doped regions. During this second N-type implantation process, the N-type heavily doped regions (140b) in the P-body of the LDMOS device may also be created. After the formation of these N-type heavily doped regions, the remaining photoresist mask is then removed from the device layout.

After, or even prior to, the formation of the heavily doped N-type regions in Step 540, at a Step 545, the smaller, heavily doped P-type regions in the source region of the LDMOS device (e.g., PW 160 in FIG. 1) may be formed. In an exemplary embodiment, another photoresist is deposited, and this photoresist is then patterned with the desired locations for the heavily doped P-type source regions to be formed in the P-body region. Then, a second P-type dopant implantation process is performed to form the heavily doped P-type regions in the source region of the LDMOS device. In other embodiments, other process parameters may be employed for implanting these heavily doped P-type regions. After implantation of the P-type heavily doped regions, the remaining photoresist material is then removed from the device layout.

At a Step 550, sidewall spacers may be formed on the sidewalls of the gates. Specifically, an oxide layer, such as a TEOS layer, may be deposited over the LDMOS device layout. An anisotropic etch is then performed on the TEOS layer, which leaves the dielectric spacers on the sidewalls of the gates. Other etching processes, either now existing or later developed, may alternatively be employed for formation of the sidewall spacers.

At a Step 555, contact pads may be formed on multiple locations for the LDMOS device. Specifically, contact pads may be formed on the heavily doped N-type regions in the drain region of the device, as well as on the tops of the gates for the device. Also, in accordance with the disclosed principles, a single-strip contact is formed for the source region of the LDMOS device. As described above, this source contact pad is formed as a single, elongated strip extending on top of the heavily doped N-type region(s) and P-type region(s) in the source region. The processing steps employed for forming these contact pads may be conventional processes, for example, employing cobalt silicide or other advantageous alloy, and then performing a salicide process to finish creating the contact pads. However, in contrast to conventional techniques, only the single-strip contact pad is formed on the source region of the LDMOS device, in accordance with the disclosed principles.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A laterally double-diffused metal oxide semiconductor (LDMOS) device, comprising:
a first well lightly doped with a first conductive dopant and formed into a portion of a substrate, the first well having a drain region at its surface heavily doped with the first dopant;
a second well lightly doped with a second conductive dopant formed in another portion of the substrate, the second well having a source region at its surface comprising first portions heavily doped with the first dopant directly adjacent second portions heavily doped with the second dopant;
a field oxide formed at the upper surface of the substrate between the source region and the drain region, the field oxide contacting the first well and separated from the second well by a distance; and
conductive contact pads in contact with the drain region and the source region, wherein the contact pad in contact with the source regions comprises a single-strip of conductive material extending across the source region.

2. An LDMOS device according to claim 1, wherein the LDMOS device further comprises two first wells, each having a drain region, on opposing sides of the second well, and first and second field oxides, each formed between the source region and one of the drain regions, the first field oxide contacting one of the first wells and separated from the second well by a distance and the second field oxide contacting the other of the first wells and separated from the second well by a distance, the LDMOS further comprising a second gate formed partially over the second field oxide and partially over the source region.

3. An LDMOS device according to claim 1, wherein the second portion of the source region comprising the second dopant comprises a plurality of second portions comprising the second dopant, the single-strip source contact in contact with each of the plurality of source regions.

4. An LDMOS device according to claim 1, further comprising a gate formed partially over the field oxide and partially over the source region, wherein the conductive contact pads are contact with the gate, the drain region and the source region.

5. An LDMOS device according to claim 4, wherein the gate is formed directly on at least one gate oxide layer, and wherein the at least one gate oxide layer comprises a high voltage gate oxide.

6. An LDMOS device according to claim 1, wherein the contacts comprise metal silicide.

7. An LDMOS device according to claim 1, wherein the first conductive dopant comprises an N-type dopant, and the second conductive dopant comprises a P-type dopant.

8. An LDMOS device according to claim 1, further comprising a buried layer comprising the first dopant located directly under the second well.

9. A laterally double-diffused metal oxide semiconductor (LDMOS) device, comprising:
two first wells lightly doped with a first conductive dopant and formed into a portion of a substrate, the first wells each having a drain region at their surface heavily doped with the first dopant;
a second well lightly doped with a second conductive dopant formed in another portion of the substrate between the two first wells, the second well having a source region at its surface comprising first portions heavily doped with the first dopant directly adjacent second portions heavily doped with the second dopant;
first and second field oxides formed at the upper surface of the substrate between the source region and each of the drain regions, the first field oxide contacting one of the first wells and separated from the second well by a distance and the second field oxide contacting the other of the first wells and separated from the second well by a distance;
first and second gates, each gate formed partially over one of the field oxides and partially over the source region, and each gate formed directly on a gate oxide;
a buried layer comprising the first dopant located directly under the second well; and
conductive contact pads in contact with the gates, the drain regions, and the source region, wherein the contact pad in contact with the source regions comprises a single-strip of conductive material extending across the source region.

10. An LDMOS device according to claim 9, wherein the second portion of the source region comprising the second dopant comprises a plurality of second portions comprising the second dopant, the single-strip source contact in contact with each of the plurality of source regions.

11. An LDMOS device according to claim 9, wherein the gate oxide comprises a high voltage gate oxide.

12. An LDMOS device according to claim 9, wherein the contacts comprise metal silicide.

13. An LDMOS device according to claim 9, wherein the first conductive dopant comprises an N-type dopant, and the second conductive dopant comprises a P-type dopant.

14. A method of manufacturing a laterally double-diffused metal oxide semiconductor (LDMOS) device, the method comprising:
lightly doping, with a first conductive dopant, a portion of a substrate to form a first well;
heavily doping the first well with the first dopant to form a drain region at its surface;
lightly doping, with a second conductive dopant, another portion of the substrate to form a second well;
heavily doping the second well with the first and second dopants to form a source region at its surface, the source region comprising first portions heavily doped with the first dopant directly adjacent second portions heavily doped with the second dopant;
forming a field oxide at the upper surface of the substrate between the source region and the drain region, the field oxide contacting the first well and separated from the second well by a distance;
forming a gate partially over the field oxide and partially over the source region; and
forming conductive contact pads in contact with the gate, the drain region, and the source region, wherein the contact pad in contact with the source regions comprises a single-strip of conductive material extending across the source region.

15. A method according to claim 14, the method further comprising:
lightly doping two portions of the substrate to form two first wells, each of the first wells having a drain region and formed on opposing sides of the second well;
forming first and second field oxides, each formed between the source region and one of the drain regions, the first field oxide contacting one of the first wells and separated from the second well by a distance and the second field oxide contacting the other of the first wells and separated from the second well by a distance; and
forming first and second gates, each gate formed partially over one of the field oxides and partially over the source region.

16. A method according to claim 14, wherein the second portion of the source region comprising the second dopant comprises a plurality of second portions comprising the second dopant extending along the second well, the single-strip source contact in contact with each of the plurality of portions.

17. A method according to claim 14, further comprising forming at least one gate oxide layer prior to form the gate, and then forming the gate directly on the at least one gate oxide layer.

18. A method according to claim 14, wherein the contacts comprise metal silicide.

19. A method according to claim 14, wherein the first conductive dopant comprises an N-type dopant, and the second conductive dopant comprises a P-type dopant.

20. A method according to claim 14, further comprising forming a buried layer comprising the first dopant and located directly under the second well.
